(19) United States
(12) Patent Application Publication
(10) Pub. No.: US 2025/0258476 A1
(43) Pub. Date: Aug. 14, 2025

(54) DATA DIODE AND PULSE CONTROL METHOD

(71) Applicant: Azbil Corporation, Tokyo (JP)

(72) Inventors: ATSUSHI KATSUMATA, Tokyo (JP); ITSUKI TANABE, Tokyo (JP); FUMIAKI YAMASAKI, Tokyo (JP); MAMORU KAGOURA, Tokyo (JP)

(73) Assignee: Azbil Corporation, Tokyo (JP)

(21) Appl. No.: 18/973,081

(22) Filed: Dec. 8, 2024

(30) Foreign Application Priority Data
Feb. 13, 2024 (JP) 2024-019081

(51) Int. Cl. G05B 19/406

(52) U.S. Cl. CPC G05B 19/406; G05B 2219/42294

(57) ABSTRACT

To enable remote response in the case of a malfunction occurrence while ensuring security.

A transmitting side device that transmits data from an OT network, a receiving side device that transmits input data to an IT network, and a one-way communication unit that transmits data transmitted by the transmitting side device to the receiving side device are provided. The receiving side device includes a pulse generating unit that is started in response to an instruction from the IT network and generates a pulse signal. The transmitting side device includes a pulse output unit that outputs the pulse signal generated by the pulse generating unit to an OT side device connected to the OT network.

### CROSS-REFERENCE TO RELATED APPLICATION

This application claims the priority benefits of Japanese application no. 2024-019081, filed on Feb. 13, 2024. The entirety of the above-mentioned patent application is hereby incorporated by reference herein and made a part of this specification.

### BACKGROUND

### Technical Field

The disclosure relates to a data diode that performs one-way communication, and a pulse control method using the data diode.

### Description of Related Art

An OT network (control network) used in automation, such as in factories, is utilized for controlling various devices and is of high importance. In the case where the control network is hijacked with malicious intent, accidents that would not normally occur may be caused by making the control of devices abnormal.

In this manner, the highly important control network generally maintains safety thereof by not connecting to other networks.

On the other hand, it is also needed to use information generated on the control network externally, and in such cases, a data diode is effective. The data diode enables communication in merely one direction and is effective as a method to physically enhance network security (refer to, for example, Patent Literature 1 (Japanese Patent Application Laid-Open No. 2015-133558)).

In this manner, since the data diode physically enables communication in merely one direction, no network exists for a malicious individual to infiltrate even if the malicious individual attempts a hijacking. Additionally, to guarantee the above, the data diode is unable to establish even a slight information transmission path in the reverse direction.

In this manner, since the data diode enables communication in merely one direction, generally, the transmitting side is unable to obtain information from the receiving side. With the data diode, unauthorized access may almost be completely prevented.

On the other hand, in the case where information sent from the OT network side to the IT network (business network) side indicates the occurrence of abnormality, or in the case where information that should be sent for some reason is no longer being sent, it can be assumed that some kind of malfunction has occurred on the OT network side.

In response to this, in a normal network, access to the OT network side from the IT network side may be got to confirm the malfunction status, and recovery is feasible by implementing control to fix the malfunction.

However, in the case of a data diode, access to the OT network side from the IT network side is unable to be got to confirm the malfunction status, and recovery is not feasible by implementing control to fix the malfunction.

Therefore, in the case of a data diode, even if information including the occurrence of abnormality on the OT network side can be obtained, nothing can be done unless one goes to the site on the OT network side.

In factories and other facilities, labor-saving for productivity improvement is progressing, and it is often difficult to respond promptly to malfunctions on-site. This not only leads to decreased productivity due to delayed malfunction response, but also has the potential to result in the occurrence of disaster.

Thus, there is a demand to ensure security through a data diode and to be able to promptly implement appropriate responses remotely in the case of a malfunction occurrence.

The disclosure provides a data diode that ensures security and enables remote response in the case of a malfunction occurrence.

### SUMMARY

The data diode according to the disclosure includes a transmitting side device that transmits data from a control network, a receiving side device that transmits input data to a business network, and a one-way communication unit that transmits data transmitted by the transmitting side device to the receiving side device. The receiving side device includes a pulse generating unit that is started in response to an instruction from the business network and generates a pulse signal. The transmitting side device includes a pulse output unit that outputs the pulse signal generated by the pulse generating unit to a control side device connected to the control network.

According to the disclosure, with the configuration as described above, security may be ensured and remote response is enabled in the case of a malfunction occurrence.

### BRIEF DESCRIPTION OF THE DRAWINGS

FIG. 1 is a diagram showing a configuration example of a data diode according to a first embodiment.

FIG. 2 is a flowchart showing a pulse output operation example by the data diode according to the first embodiment.

FIG. 3 is a diagram showing a configuration example of the data diode according to a second embodiment.

### DESCRIPTION OF THE EMBODIMENTS

Hereinafter, embodiments will be described in detail with reference to the drawings.

### First Embodiment

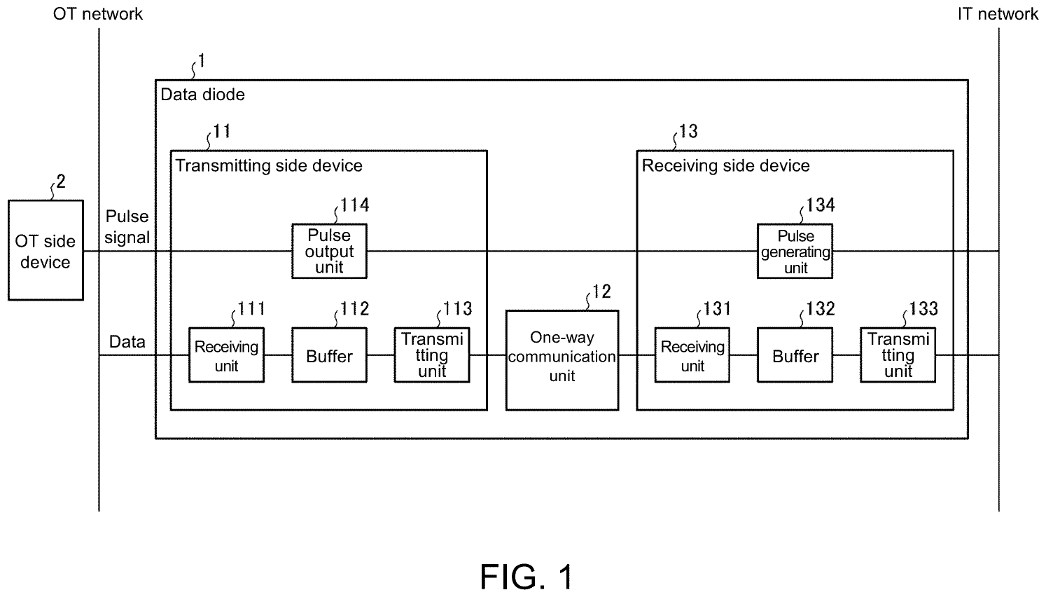

FIG. 1 is a diagram showing a configuration example of a data diode 1 according to a first embodiment.

The data diode 1 is an apparatus that performs one-way communication from an OT network (control network) to an IT network (business network).

In the data diode 1 according to the first embodiment, the point is to achieve needed functions without creating an information transmission path in the reverse direction. Here, the needed function refers to the capability to fix malfunction in the case of an occurrence of malfunction on the transmitting side. In other words, the point is to realize the function, which is common in normal communication, even in the data diode 1 in which information transmission in the reverse direction is not feasible.

The data diode 1 includes, for example as shown in FIG. 1, a transmitting side device 11, a one-way communication unit 12, and a receiving side device 13.

Additionally, as shown in FIG. 1, one or more OT side devices (control side devices) 2 are connected to the OT network. FIG. 1 shows one OT side device 2.

The transmitting side device 11 transmits data from the OT network to the one-way communication unit 12.

The transmitting side device 11 includes, for example as shown in FIG. 1, a receiving unit 111, a buffer 112, a transmitting unit 113, and a pulse output unit 114.

The receiving unit 111 receives data from the OT network.

The buffer 112 temporarily accumulates data received by the receiving unit 111.

The transmitting unit 113 transmits data accumulated in the buffer 112 to the one-way communication unit 12.

The pulse output unit 114 outputs a pulse signal generated by the pulse generating unit 134, which will be described later, in the receiving side device 13 to the OT side device 2 connected to the OT network.

In other words, the output terminal of the pulse output unit 114 is connected to the pulse input terminal of the OT side device 2, and the pulse signal output by the pulse output unit 114 is transmitted to the OT side device 2. Then, the OT side device 2 receives the pulse signal and uses the pulse signal as a signal to resolve an abnormal state, such as for reset or restart.

In the case where multiple OT side devices 2 are connected to the OT network, one or more pulse output units 114 may be provided, and each may be configured to output a pulse signal to a corresponding one of the OT side devices 2.

Additionally, in the case where multiple OT side devices 2 are connected to the OT network, a single pulse output unit 114 may be provided and configured to output a pulse signal to each of the OT side devices 2.

It should be noted that in FIG. 1, the transmitting side device 11 is shown to include the receiving unit 111, the buffer 112, and the transmitting unit 113 as components for transmitting data from the OT network to the one-way communication unit 12. However, the transmitting side device 11 is not limited to the above configuration and may have any configuration capable of transmitting data from the OT network to the one-way communication unit 12.

The one-way communication unit 12 transmits data from the transmitting side device 11 to the receiving side device 13.

The receiving side device 13 transmits data from the transmitting side device 11 via the one-way communication unit 12 to the IT network.

The receiving side device 13 includes, for example as shown in FIG. 1, a receiving unit 131, a buffer 132, a transmitting unit 133, and a pulse generating unit 134.

The receiving unit 131 receives data from the transmitting side device 11 via the one-way communication unit 12.

The buffer 132 temporarily accumulates data received by the receiving unit 131.

The transmitting unit 133 transmits the data accumulated by the buffer 132 to the IT network.

The pulse generating unit 134 is started in response to an instruction from the IT network and generates a pulse signal.

In other words, in the case where the IT network side determines that the OT side device 2 is in an abnormal state, the pulse generating unit 134 is started by transmitting specific data to a specific port of the IP address of the receiving side device 13 from the IT network side. Then, the pulse generating unit 134 generates a pulse signal. The above-mentioned specific port and specific data are predetermined port and data, and may be designed and modified as appropriate.

Examples of cases where the IT network performs the above-mentioned instruction include: in the case where an abnormality occurs in the OT side device 2 and recovery is feasible by resetting (restarting); in the case where no person (who understands) is on site or the OT side device 2 is unable to be operated (for example, when the facility is unable to be accessed); or in the case where rapid recovery is needed.

In such cases, for example, under the instruction of an organization (such as a maintenance company) managing the network using the data diode 1, specific data is transmitted to a specific port from the IT network side (using an application as needed), or the maintenance company or similar entity remotely accesses the IT network and transmits specific data to a specific port.

It should be noted that in FIG. 1, the receiving side device 13 is shown to include the receiving unit 131, the buffer 132, and the transmitting unit 133 as components for transmitting data from the transmitting side device 11 via the one-way communication unit 12 to the IT network. However, the receiving side device 13 is not limited to the above configuration and may have any configuration capable of transmitting data from the transmitting side device 11 via the one-way communication unit 12 to the IT network.

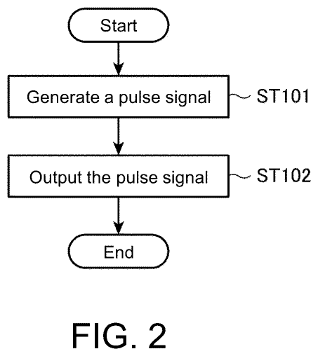

Next, a pulse control operation example by the data diode 1 according to the first embodiment shown in FIG. 1 will be described with reference to FIG. 2.

In the data diode 1 according to the first embodiment, the transmitting side device 11 transmits data from the OT network to the one-way communication unit 12, the one-way communication unit 12 transmits the data from the transmitting side device 11 to the receiving side device 13, and the receiving side device 13 transmits the data from the transmitting side device 11 via the one-way communication unit 12 to the IT network.

In the pulse control operation example by the data diode 1 according to the first embodiment shown in FIG. 1, first, as shown in FIG. 2 for example, the pulse generating unit 134 in the receiving side device 13 is started in response to an instruction from the IT network and generates a pulse signal (step ST101). In other words, the pulse generating unit 134 is started when specific data is transmitted from the IT network to a specific port of the IP address of the receiving side device 13. Then, the pulse generating unit 134 generates a pulse signal.

Next, the pulse output unit 114 in the transmitting side device 11 outputs the pulse signal generated by the pulse generating unit 134 to the OT side device 2 connected to the OT network (step ST102). In other words, the output terminal of the pulse output unit 114 is connected to the pulse input terminal of the OT side device 2, and the pulse signal output by the pulse output unit 114 is transmitted to the OT side device 2. Then, the OT side device 2 receives the pulse signal and uses the pulse signal as a signal to resolve an abnormal state, such as for reset or restart.

In the case where multiple OT side devices 2 are connected to the OT network, one or more pulse output units 114 may be provided, and each may be configured to output a pulse signal to a corresponding one of the OT side devices 2.

Additionally, in the case where multiple OT side devices 2 are connected to the OT network, a single pulse output unit 114 may be provided and configured to output a pulse signal to each of the OT side devices 2.

As described above, in the data diode 1 according to the first embodiment, the pulse generating unit 134 of the receiving side device 13 is started and generates a pulse signal in response to specific data being transmitted from the IT network side to a specific port of the IP address of the receiving side device 13.

Then, the pulse output unit 114 of the transmitting side device 11 outputs the pulse signal generated by the pulse generating unit 134 of the receiving side device 13 to the OT side device 2 via the OT network. In other words, the output terminal of the pulse output unit 114 is connected to the pulse input terminal of the OT side device 2, and the pulse signal is transmitted to the OT side device 2.

The OT side device 2, upon receiving the pulse signal, uses the pulse signal as a signal to resolve an abnormal state, such as for reset or restart.

In this manner, the data diode 1 according to the first embodiment generates a pulse signal based on an instruction from the IT network side, and transmits the pulse signal to the OT network side. Moreover, at this time, merely the pulse signal is transmitted, not information. The pulse signal is then utilized to return the OT side device 2 in an abnormal state to a normal state.

It should be noted that if the OT side device 2 is unconditionally reset or restarted upon input of the pulse signal, normal operation is unable to be expected in cases such as when pulses occur frequently.

In cases where the above becomes an issue, a mechanism can be implemented in the OT side device 2 to ignore the input of the pulse signal during normal operation, and to enable the input of the pulse signal merely in the case of an abnormality occurring. Such a mechanism can be easily realized by providing a watchdog timer or similar component in the OT side device 2.

As described above, according to the first embodiment, the data diode 1 includes the transmitting side device 11 that transmits data from the OT network, the receiving side device 13 that transmits input data to the IT network, and the one-way communication unit 12 that transmits data transmitted by the transmitting side device 11 to the receiving side device 13. The receiving side device 13 includes the pulse generating unit 134 that is started in response to an instruction from the IT network and generates a pulse signal. The transmitting side device 11 includes the pulse output unit 114 that outputs the pulse signal generated by the pulse generating unit 134 to the OT side device 2 connected to the OT network.

As a result, the data diode 1 according to the first embodiment enables remote response in the case of a malfunction occurrence while ensuring security.

Furthermore, according to the first embodiment, there are multiple OT side devices 2, and one or more pulse output units 114 are provided, each outputting a pulse signal to a corresponding one of the OT side devices 2.

Moreover, according to the first embodiment, there are multiple OT side devices 2, and a single pulse output unit 114 is provided, outputting a pulse signal to each of the OT side devices 2.

As a result, the data diode 1 according to the first embodiment enables remote response in the case of a malfunction occurrence while ensuring security, even when there are multiple OT side devices 2 connected to the OT network.

Furthermore, according to the first embodiment, the pulse control method is a pulse control method in the data diode 1 which includes the transmitting side device 11 that transmits data from the OT network, the receiving side device 13 that transmits input data to the IT network, and the one-way communication unit 12 that transmits data transmitted by the transmitting side device 11 to the receiving side device 13. In the pulse control method, the pulse generating unit 134 in the receiving side device 13 is started in response to an instruction from the IT network and generates a pulse signal, and the pulse output unit 114 in the transmitting side device 11 outputs the pulse signal generated by the pulse generating unit 134 to the OT side device 2 connected to the OT network.

As a result, the pulse control method according to the first embodiment enables remote response in the case of a malfunction occurrence while ensuring security.

### Second Embodiment

A second embodiment describes a configuration example in which the pulse disabling function using a watchdog timer is provided within the data diode 1 instead of in the OT side device 2.

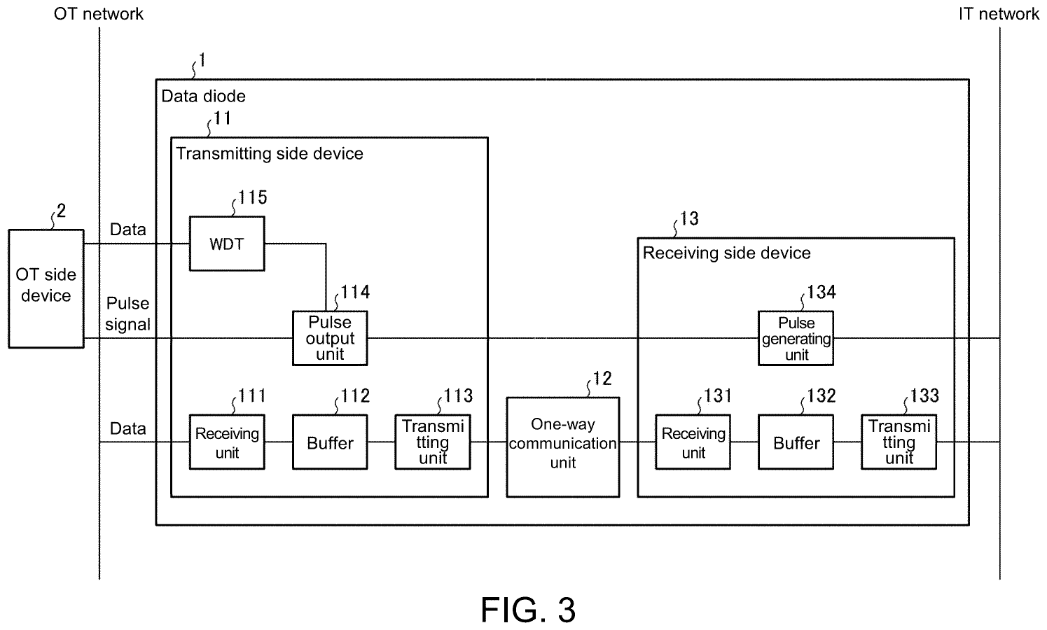

FIG. 3 is a diagram showing a configuration example of the data diode 1 according to the second embodiment. In the data diode 1 according to the second embodiment shown in FIG. 3, a watchdog timer (WDT) 115 is added to the transmitting side device 11 compared to the data diode 1 according to the first embodiment shown in FIG. 1. The configuration example in the data diode 1 according to the second embodiment shown in FIG. 3 is similar to the configuration example of the data diode 1 according to the first embodiment, the same reference numerals are used, and merely the different parts will be described.

The watchdog timer 115 performs status monitoring of the OT side device 2 by receiving data from the OT side device 2 via the OT network.

In response to determining that the reception of data from the OT side device 2 has been interrupted for a certain period, the watchdog timer 115 determines that the state of the OT side device 2 is in an abnormal state, and outputs a signal indicating the determination to the pulse output unit 114.

In the second embodiment, the pulse output unit 114 outputs the pulse signal generated by the pulse generating unit 134 in the case where the OT side device 2 is determined to be in an abnormal state by the watchdog timer 115. In other words, the pulse output unit 114 outputs the pulse signal according to the presence or absence of a signal from the watchdog timer 115. More specifically, the pulse output unit 114 does not output the pulse signal in the absence of a signal from the watchdog timer 115, and outputs the pulse signal in the presence of a signal from the watchdog timer 115.

In this manner, the data diode 1 according to the second embodiment includes a pulse suppression function for the pulse output unit 114 in the transmitting side device 11. The OT side device 2 can suppress the output of the pulse signal for a certain time by transmitting specific data to a specific port of the IP address in the transmitting side device 11 via the OT network. The above-mentioned specific port and specific data are predetermined port and data, and may be designed and modified as appropriate.

In response to an occurrence of abnormality in the OT side device 2, the communication that suppresses the output of the pulse signal ceases to occur. As a result, the transmitting side device 11 in the data diode 1 is unable to suppress the output of the pulse signal at the pulse output unit 114, and the pulse signal is transmitted to the pulse input terminal of the OT side device 2. It should be noted that the abnormal state can be resolved by configuring the OT side device 2 to return to normal operation through actions such as restarting in response to the input of the pulse signal.

Moreover, in the case where the OT side device 2 is in an abnormal state, merely the pulse signal for returning the OT side device 2 to normal operation is generated, preventing unauthorized access.

It should be noted that in the case where the OT side device 2 is in a normal state, the pulse signal is not transmitted from the transmitting side device 11 to the OT side device 2 due to pulse suppression. Therefore, the function of the data diode 1 is maintained.

As described above, according to the second embodiment, the transmitting side device 11 includes the watchdog timer 115 that performs status monitoring of the OT side device 2 by receiving data from the OT side device 2, and the pulse output unit 114 outputs the pulse signal generated by the pulse generating unit 134 in the case where the OT side device 2 is determined to be in an abnormal state by the watchdog timer 115.

As a result, the data diode 1 according to the second embodiment can be expected to be in normal operation in the OT side device 2.

It should be noted that the respective embodiments may be freely combined, or any of the components in the respective embodiments may be modified, or any of the components in the respective embodiments may be omitted.

What is claimed is:

1. A data diode, comprising:
a transmitting side device, transmitting data from a control network;
a receiving side device, transmitting input data to a business network; and
a one-way communication unit, transmitting data transmitted by the transmitting side device to the receiving side device, and
the receiving side device comprising
a pulse generating unit that is started in response to an instruction from the business network and generates a pulse signal, and
the transmitting side device comprising
a pulse output unit that outputs the pulse signal generated by the pulse generating unit to a control side device connected to the control network.

2. The data diode according to claim 1, wherein
the transmitting side device comprises
a watchdog timer that performs status monitoring of the control side device by receiving data from the control side device, and
the pulse output unit outputs the pulse signal generated by the pulse generating unit in the case where the control side device is determined to be in an abnormal state by the watchdog timer.

3. The data diode according to claim 1, wherein
a plurality of the control side devices is provided, and
the pulse output unit is provided with one or more units, each outputting a pulse signal to a corresponding one of the control side devices.

4. The data diode according to claim 1, wherein
a plurality of the control side devices is provided, and
the pulse output unit is provided as a single unit, and outputs a pulse signal to each of a plurality of the control side devices.

5. A pulse control method in a data diode which comprises
a transmitting side device that transmits data from a control network,
a receiving side device that transmits input data to a business network, and
a one-way communication unit that transmits data transmitted by the transmitting side device to the receiving side device, the pulse control method comprising:
starting a pulse generating unit in the receiving side device in response to an instruction from the business network, and generating, by the pulse generating unit, a pulse signal; and
outputting, by a pulse output unit in the transmitting side device, the pulse signal generated by the pulse generating unit to a control side device connected to the control network.
